(19) United States
(12) Patent Application Publication
(10) Pub. No.: US 2007/0249078 A1
(43) Pub. Date: Oct. 25, 2007

(54) Non-planar surface structures and process for microelectromechanical systems

(76) Inventors: Ming-Hau Tung, San Francisco, CA (US); Sriram Akella, Fremont, CA (US); William J. Cummings, Millbrae, CA (US); Lior Kogut, Sunnyvale, CA (US)

Correspondence Address: KNOBBE, MARTENS, OLSON & BEAR, LLP, 2040 MAIN STREET, FOURTEENTH FLOOR, IRVINE, CA, 92614, US

(21) Appl. No.: 11/406,776

(22) Filed: Apr. 19, 2006

(51) Int. Cl. H01L 21/00

(52) U.S. Cl. 438/48

(57) ABSTRACT

Methods of making MEMS devices including interferometric modulators involve depositing various layers, including stationary layers, movable layers and sacrificial layers, on a substrate. Apertures are formed in one or more of the various layers so as to form a non-planar surface on the movable and/or the stationary layers. Other layers may be formed over the formed apertures. Removal of the sacrificial layer from between the resulting non-planar movable and/or stationary layers results in a released MEMS device having reduced contact area and/or a larger surface separation between the movable and stationary layers when the MEMS device is actuated. The reduced contact area results in lower adhesion forces and reduced stiction during actuation of the MEMS device. These methods may be used to manufacture released and unreleased interferometric modulators.

### CROSS-REFERENCE TO RELATED APPLICATIONS

This application is related to U.S. application Ser. No. 11/189,690, filed Jul. 26, 2005 entitled SYSTEM AND METHOD FOR MICRO-ELECTROMECHANICAL OPERATION OF AN INTERFEROMETRIC MODULATOR; NON-PLANAR SURFACE STRUCTURES AND PROCESS FOR MICROELECTROMECHANICAL SYSTEMS (Atty. Docket No. QCO.052A, filed on even date herewith); NON-PLANAR SURFACE STRUCTURES AND PROCESS FOR MICROELECTROMECHANICAL SYSTEMS (Atty. Docket No. QCO.051A, filed on even date herewith); MICROELECTROMECHANICAL DEVICE AND METHOD UTILIZING NANOPARTICLES (Atty. Docket No. QCO.060A, filed on even date herewith); and MICROELECTROMECHANICAL DEVICE AND METHOD UTILIZING A POROUS SURFACE (Atty. Docket No. QCO.061A, filed on even date herewith).

### BACKGROUND OF THE INVENTION

1. Field of the Invention

This invention relates to microelectromechanical systems. More particularly, this invention relates to methods and apparatus for improving the performance of microelectromechanical systems such as interferometric modulators.

2. Description of the Related Art

Microelectromechanical systems (MEMS) include micro mechanical elements, actuators, and electronics. Micromechanical elements may be created using deposition, etching, and or other micromachining processes that etch away parts of substrates and/or deposited material layers or that add layers to form electrical and electromechanical devices. One type of MEMS device is called an interferometric modulator. As used herein, the term interferometric modulator or interferometric light modulator refers to a device that selectively absorbs and/or reflects light using the principles of optical interference. In certain embodiments, an interferometric modulator may comprise a pair of conductive plates, one or both of which may be transparent and/or reflective in whole or part and capable of relative motion upon application of an appropriate electrical signal. In a particular embodiment, one plate may comprise a stationary layer deposited on a substrate and the other plate may comprise a metallic membrane separated from the stationary layer by an air gap. As described herein in more detail, the position of one plate in relation to another can change the optical interference of light incident on the interferometric modulator. Such devices have a wide range of applications, and it would be beneficial in the art to utilize and/or modify the characteristics of these types of devices so that their features can be exploited in improving existing products and creating new products that have not yet been developed.

### SUMMARY OF THE INVENTION

The system, method, and devices of the invention each have several aspects, no single one of which is solely responsible for its desirable attributes. Without limiting the scope of this invention, its more prominent features will now be discussed briefly. After considering this discussion, and particularly after reading the section entitled “Detailed Description of Certain Embodiments” one will understand how the features of this invention provide advantages over other display devices.

An embodiment provides a method of making a MEMS device that includes providing a substrate, forming a first sacrificial layer over the substrate and forming at least one aperture in the first sacrificial layer. The method further includes forming a second sacrificial layer over the first sacrificial layer and the at least one formed aperture, and forming an electrically conductive layer over the second sacrificial layer, thereby forming a non-planar interface between the electrically conductive layer and the second sacrificial layer. The method further includes removing the first and second sacrificial layers to form a cavity between the substrate and the electrically conductive layer.

Another embodiment provides a method of making an interferometric modulator that includes providing a substrate, forming a first layer over the substrate, and forming at least one aperture in the first layer. The method further includes forming a second layer over at least a portion of the first layer and the at least one aperture, wherein the first layer is thinner than the second layer as measured perpendicular to the substrate, forming a sacrificial layer over at least a portion of the second layer, thereby forming a non-planar interface between the sacrificial layer and the second layer, and forming an electrically conductive layer over the sacrificial layer. In one aspect of this embodiment, the sacrificial layer is removable to thereby form a cavity between the second layer and the electrically conductive layer. Another embodiment provides an unreleased interferometric modulator made by such a method.

Another embodiment provides an unreleased MEMS device that includes a substrate and a discontinuous first layer over the substrate, where the discontinuous first layer comprising at least one aperture. The unreleased MEMS device further includes a second layer continuous over at least a portion of the discontinuous first layer and the at least one aperture, wherein the first layer is thinner than the second layer as measured perpendicular to the substrate, a sacrificial layer over at least a portion of the second layer, a non-planar interface between the sacrificial layer and the second layer, and an electrically conductive layer over the sacrificial layer. In one aspect of the embodiment, the sacrificial layer is removable to thereby form a cavity between the second layer and the electrically conductive layer.

Another embodiment provides an interferometric modulator that includes a substrate, and a first discontinuous layer over at least a portion of the substrate, the discontinuous first layer comprising at least one aperture. The interferometric modulator further includes a second layer continuous over at least a portion of the first discontinuous layer and the at least one aperture, the second layer comprising a non-planar surface, wherein the first discontinuous layer is thinner than the second layer as measured perpendicular to the substrate, a electrically conductive layer separated from the second layer by a cavity, and a support structure arranged over the substrate and configured to support the electrically conductive layer. Another embodiment provides an array of such interferometric modulators. Another embodiment provides a display device that includes such an array of interferometric modulators. The display device of this embodiment further includes a processor configured to communicate with the array and configured to process image data, and a memory device configured to communicate with the processor.

These and other embodiments are described in greater detail below.

### BRIEF DESCRIPTION OF THE DRAWINGS

FIG. 1 is an isometric view depicting a portion of one embodiment of an interferometric modulator display in which a movable reflective layer of a first interferometric modulator is in a relaxed position and a movable reflective layer of a second interferometric modulator is in an actuated position.

FIG. 2 is a system block diagram illustrating one embodiment of an electronic device incorporating a 3×3 interferometric modulator display.

FIG. 3 is a diagram of movable mirror position versus applied voltage for one exemplary embodiment of an interferometric modulator of FIG. 1.

FIG. 4 is an illustration of a set of row and column voltages that may be used to drive an interferometric modulator display.

FIG. 5A illustrates one exemplary frame of display data in the 3×3 interferometric modulator display of FIG. 2.

FIG. 5B illustrates one exemplary timing diagram for row and column signals that may be used to write the frame of FIG. 5A.

FIGS. 6A and 6B are system block diagrams illustrating an embodiment of a visual display device comprising a plurality of interferometric modulators.

FIG. 7A is a cross section of the device of FIG. 1.

FIG. 7B is a cross section of an alternative embodiment of an interferometric modulator.

FIG. 7C is a cross section of another alternative embodiment of an interferometric modulator.

FIG. 7D is a cross section of yet another alternative embodiment of an interferometric modulator.

FIG. 7E is a cross section of an additional alternative embodiment of an interferometric modulator.

FIG. 8 is a flow diagram illustrating certain steps in an embodiment of a method of making an interferometric modulator.

FIG. 9 is a flow diagram illustrating an embodiment of a method of making a MEMS device.

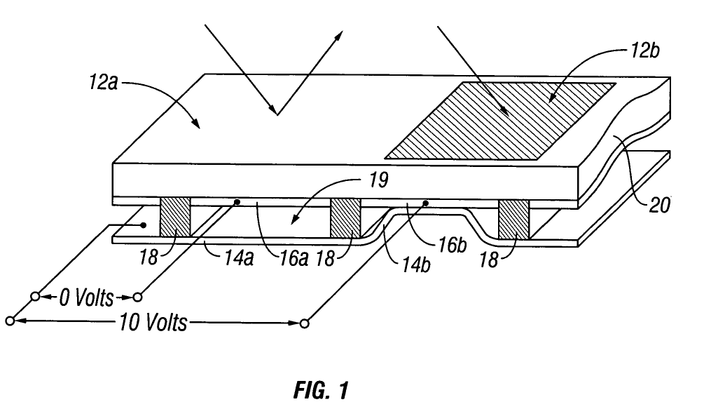

FIGS. 1Oa through 10h schematically illustrate an embodiment of a method for fabricating a MEMS device.

FIG. 11 is a flow diagram illustrating an embodiment of a method of making an interferometric modulator.

FIGS. 12a through 12h schematically illustrate an embodiment of a method for fabricating an interfereometric modulator.

FIGS. 13A through 13D schematically illustrate another embodiment of a method for fabricating a MEMS device.

FIG. 14 is a side cross sectional view of alternative embodiments of non-planar surface formations.

FIG. 15 is a top cross sectional view of alternative embodiments of non-planar surface formations.

The Figures are not drawn to scale.

### DETAILED DESCRIPTION OF CERTAIN EMBODIMENTS

The following detailed description is directed to certain specific embodiments of the invention. However, the invention can be embodied in a multitude of different ways. In this description, reference is made to the drawings wherein like parts are designated with like numerals throughout. As will be apparent from the following description, the embodiments may be implemented in any device that is configured to display an image, whether in motion (e.g., video) or stationary (e.g., still image), and whether textual or pictorial. More particularly, it is contemplated that the embodiments may be implemented in or associated with a variety of electronic devices such as, but not limited to, mobile telephones, wireless devices, personal data assistants (PDAs), hand-held or portable computers, GPS receivers/navigators, cameras, MP3 players, camcorders, game consoles, wrist watches, clocks, calculators, television monitors, flat panel displays, computer monitors, auto displays (e.g., odometer display, etc.), cockpit controls and/or displays, display of camera views (e.g., display of a rear view camera in a vehicle), electronic photographs, electronic billboards or signs, projectors, architectural structures, packaging, and aesthetic structures (e.g., display of images on a piece of jewelry). MEMS devices of similar structure to those described herein can also be used in non-display applications such as in electronic switching devices.

An embodiment provides methods of making interferometric modulators with decreased contact area between a movable surface and another surface so as to reduce adhesion forces between the two surfaces.

One interferometric modulator display embodiment comprising an interferometric MEMS display element is illustrated in FIG. 1. In these devices, the pixels are in either a bright or dark state. In the bright (“on” or “open”) state, the display element reflects a large portion of incident visible light to a user. When in the dark (“off” or “closed”) state, the display element reflects little incident visible light to the user. Depending on the embodiment, the light reflectance properties of the “on” and “off” states may be reversed. MEMS pixels can be configured to reflect predominantly at selected colors, allowing for a color display in addition to black and white.

FIG. 1 is an isometric view depicting two adjacent pixels in a series of pixels of a visual display, wherein each pixel comprises a MEMS interferometric modulator. In some embodiments, an interferometric modulator display comprises a row/column array of these interferometric modulators. Each interferometric modulator includes a pair of reflective layers positioned at a variable and controllable distance from each other to form a resonant optical cavity with at least one variable dimension. In one embodiment, one of the reflective layers may be moved between two positions. In the first position, referred to herein as the relaxed position, the movable reflective layer is positioned at a relatively large distance from a fixed partially reflective layer. In the second position, referred to herein as the actuated position, the movable reflective layer is positioned more closely adjacent to the partially reflective layer. Incident light that reflects from the two layers interferes constructively or destructively depending on the position of the movable reflective layer, producing either an overall reflective or non-reflective state for each pixel.

The depicted portion of the pixel array in FIG. 1 includes two adjacent interferometric modulators 12a and 12b. In the interferometric modulator 12a on the left, a movable reflective layer 14a is illustrated in a relaxed position at a predetermined distance from an optical stack 16a, which includes a partially reflective layer. In the interferometric modulator 12b on the right, the movable reflective layer 14b is illustrated in an actuated position adjacent to the optical stack 16b.

The optical stacks 16a and 16b (collectively referred to as optical stack 16), as referenced herein, typically comprise of several fused layers, which can include an electrode layer, such as indium tin oxide (ITO), a partially reflective layer, such as chromium, and a transparent dielectric. The optical stack 16 is thus electrically conductive, partially. transparent and partially reflective, and may be fabricated, for example, by depositing one or more of the above layers onto a transparent substrate 20. The partially reflective layer can be formed from a variety of materials that are partially reflective such as various metals, semiconductors, and dielectrics. The partially reflective layer can be formed of one or more layers of materials, and each of the layers can be formed of a single material or a combination of materials.

In some embodiments, the layers of the optical stack are patterned into parallel strips, and may form row electrodes in a display device as described further below. The movable reflective layers 14a, 14b may be formed as a series of parallel strips of a deposited metal layer or layers (orthogonal to the row electrodes of 16a, 16b) deposited on top of posts 18 and an intervening sacrificial material deposited between the posts 18. When the sacrificial material is etched away, the movable reflective layers 14a, 14b are separated from the optical stacks 16a, 16b by a defined gap 19. A highly conductive and reflective material such as aluminum may be used for the reflective layers 14, and these strips may form column electrodes in a display device.

With no applied voltage, the cavity 19 remains between the movable reflective layer 14a and optical stack 16a, with the movable reflective layer 14a in a mechanically relaxed state, as illustrated by the pixel 12a in FIG. 1. However, when a potential difference is applied to a selected row and column, the capacitor formed at the intersection of the row and column electrodes at the corresponding pixel becomes charged, and electrostatic forces pull the electrodes together. If the voltage is high enough, the movable reflective layer 14 is deformed and is forced against the optical stack 16. A dielectric layer (not illustrated in this Figure) within the optical stack 16 may prevent shorting and control the separation distance between layers 14 and 16, as illustrated by pixel 12b on the right in FIG. 1. The behavior is the same regardless of the polarity of the applied potential difference. In this way, row/column actuation that can control the reflective vs. non-reflective pixel states is analogous in many ways to that used in conventional LCD and other display technologies.

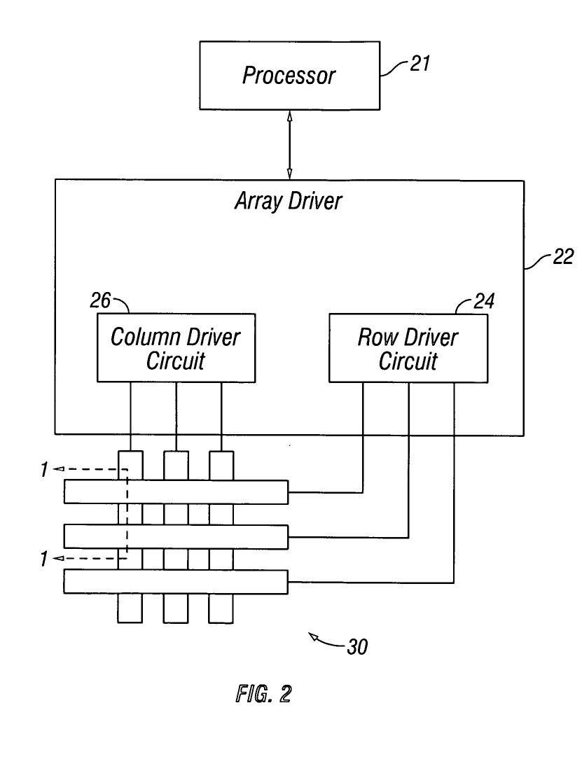

FIGS. 2 through 5B illustrate one exemplary process and system for using an array of interferometric modulators in a display application.

FIG. 2 is a system block diagram illustrating one embodiment of an electronic device that may incorporate aspects of the invention. In the exemplary embodiment, the electronic device includes a processor 21 which may be any general purpose single- or multi-chip microprocessor such as an ARM, Pentium®, Pentium II®, Pentium III®, Pentium IV®, Pentium® Pro, an 8051, a MIPS®, a Power PC®, an ALPHA®, or any special purpose microprocessor such as a digital signal processor, microcontroller, or a programmable gate array. As is conventional in the art, the processor 21 may be configured to execute one or more software modules. In addition to executing an operating system, the processor may be configured to execute one or more software applications, including a web browser, a telephone application, an email program, or any other software application.

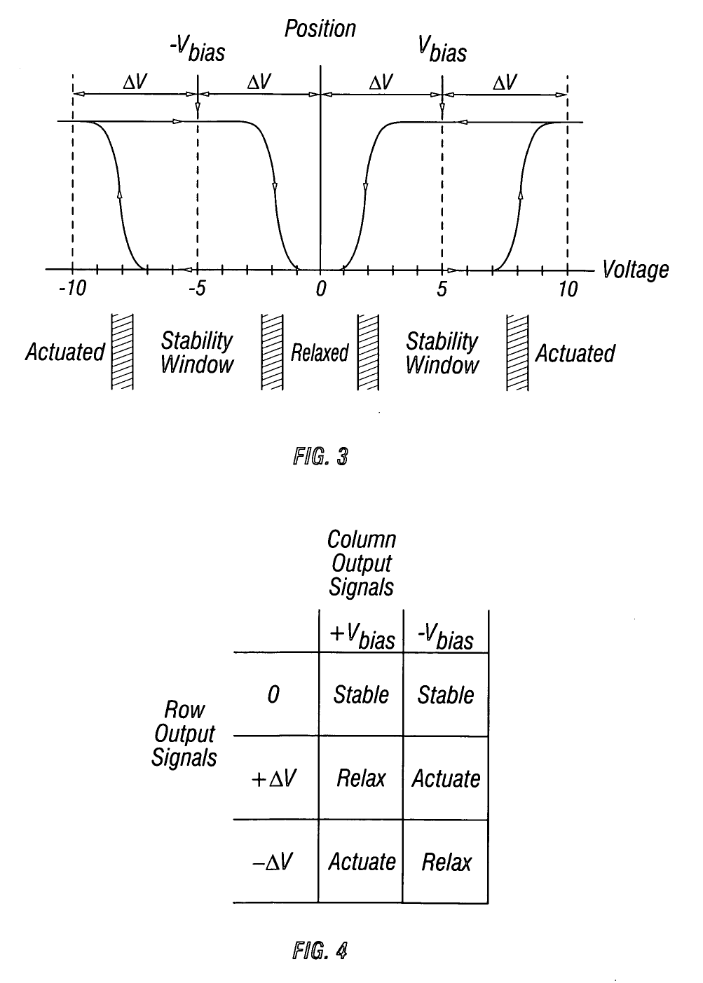

In one embodiment, the processor 21 is also configured to communicate with an array driver 22. In one embodiment, the array driver 22 includes a row driver circuit 24 and a column driver circuit 26 that provide signals to a display array or panel 30. The cross section of the array illustrated in FIG. 1 is shown by the lines 1-1 in FIG. 2. For MEMS interferometric modulators, the row/column actuation protocol may take advantage of a hysteresis property of these devices illustrated in FIG. 3. It may require, for example, a 10 volt potential difference to cause a movable layer to deform from the relaxed state to the actuated state. However, when the voltage is reduced from that value, the movable layer maintains its state as the voltage drops back below 10 volts. In the exemplary embodiment of FIG. 3, the movable layer does not relax completely until the voltage drops below 2 volts. There is thus a range of voltage, about 3 to 7 V in the example illustrated in FIG. 3, where there exists a window of applied voltage within which the device is stable in either the relaxed or actuated state. This is referred to herein as the “hysteresis window” or “stability window.” For a display array having the hysteresis characteristics of FIG. 3, the row/column actuation protocol can be designed such that during row strobing, pixels in the strobed row that are to be actuated are exposed to a voltage difference of about 10 volts, and pixels that are to be relaxed are exposed to a voltage difference of close to zero volts. After the strobe, the pixels are exposed to a steady state voltage difference of about 5 volts such that they remain in whatever state the row strobe put them in. After being written, each pixel sees a potential difference within the “stability window” of 3-7 volts in this example. This feature makes the pixel design illustrated in FIG. 1 stable under the same applied voltage conditions in either an actuated or relaxed pre-existing state. Since each pixel of the interferometric modulator, whether in the actuated or relaxed state, is essentially a capacitor formed by the fixed and moving reflective layers, this stable state can be held at a voltage within the hysteresis window with almost no power dissipation. Essentially no current flows into the pixel if the applied potential is fixed.

In typical applications, a display frame may be created by asserting the set of column electrodes in accordance with the desired set of actuated pixels in the first row. A row pulse is then applied to the row 1 electrode, actuating the pixels corresponding to the asserted column lines. The asserted set of column electrodes is then changed to correspond to the desired set of actuated pixels in the second row. A pulse is then applied to the row 2 electrode, actuating the appropriate pixels in row 2 in accordance with the asserted column electrodes. The row 1 pixels are unaffected by the row 2 pulse, and remain in the state they were set to during the row 1 pulse. This may be repeated for the entire series of rows in a sequential fashion to produce the frame. Generally, the frames are refreshed and/or updated with new display data by continually repeating this process at some desired number of frames per second. A wide variety of protocols for driving row and column electrodes of pixel arrays to produce display frames are also well known and may be used in conjunction with the present invention.

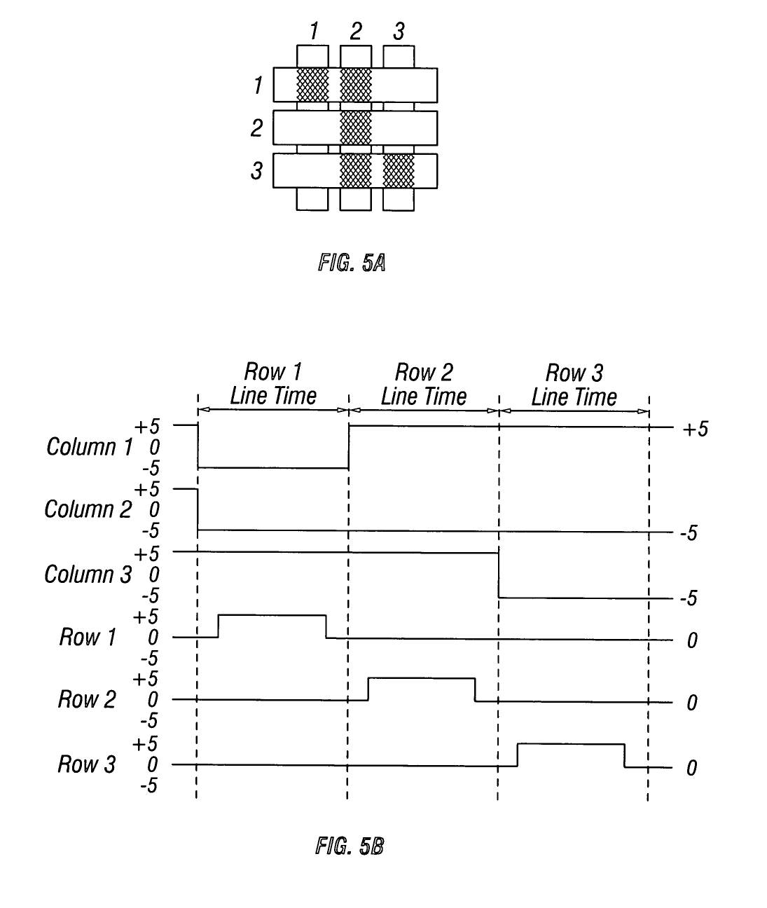

FIGS. 4, 5A, and 5B illustrate one possible actuation protocol for creating a display frame on the 3×3 array of FIG. 2. FIG. 4 illustrates a possible set of column and row voltage levels that may be used for pixels exhibiting the hysteresis curves of FIG. 3. In the FIG. 4 embodiment, actuating a pixel involves setting the appropriate column to −V_{bias}, and the appropriate row to +ΔV, which may correspond to −5 volts and +5 volts respectively Relaxing the pixel is accomplished by setting the appropriate column to +V_{bias}, and the appropriate row to the same +ΔV, producing a zero volt potential difference across the pixel. In those rows where the row voltage is held at zero volts, the pixels are stable in whatever state they were originally in, regardless of whether the column is at +V_{bias}, or −V_{bias}. As is also illustrated in FIG. 4, it will be appreciated that voltages of opposite polarity than those described. above can be used, e.g., actuating a pixel can involve setting the appropriate column to +V_{bias}, and the appropriate row to −ΔV. In this embodiment, releasing the pixel is accomplished by setting the appropriate column to −V_{bias}, and the appropriate row to the same −ΔV, producing a zero volt potential difference across the pixel.

FIG. 5B is a timing diagram showing a series of row and column signals applied to the 3×3 array of FIG. 2 which will result in the display arrangement illustrated in FIG. 5A, where actuated pixels are non-reflective. Prior to writing the frame illustrated in FIG. 5A, the pixels can be in any state, and in this example, all the rows are at 0 volts, and all the columns are at +5 volts. With these applied voltages, all pixels are stable in their existing actuated or relaxed states.

In the FIG. 5A frame, pixels (1,1), (1,2), (2,2), (3,2) and (3,3) are actuated. To accomplish this, during a “line time” for row 1, columns 1 and 2 are set to −5 volts, and column 3 is set to +5 volts. This does not change the state of any pixels, because all the pixels remain in the 3-7 volt stability window. Row 1 is then strobed with a pulse that goes from 0, up to 5 volts, and back to zero. This actuates the (1,1) and (1,2) pixels and relaxes the (1,3) pixel. No other pixels in the array are affected. To set row 2 as desired, column 2 is set to −5 volts, and columns 1 and 3 are set to +5 volts. The same strobe applied to row 2 will then actuate pixel (2,2) and relax pixels (2,1) and (2,3). Again, no other pixels of the array are affected. Row 3 is similarly set by setting columns 2 and 3 to −5 volts, and column 1 to +5 volts. The row 3 strobe sets the row 3 pixels as shown in FIG. 5A. After writing the frame, the row potentials are zero, and the column potentials can remain at either +5 or −5 volts, and the display is then stable in the arrangement of FIG. 5A. It will be appreciated that the same procedure can be employed for arrays of dozens or hundreds of rows and columns. It will also be appreciated that the timing, sequence, and levels of voltages used to perform row and column actuation can be varied widely within the general principles outlined above, and the above example is exemplary only, and any actuation voltage method can be used with the systems and methods described herein.

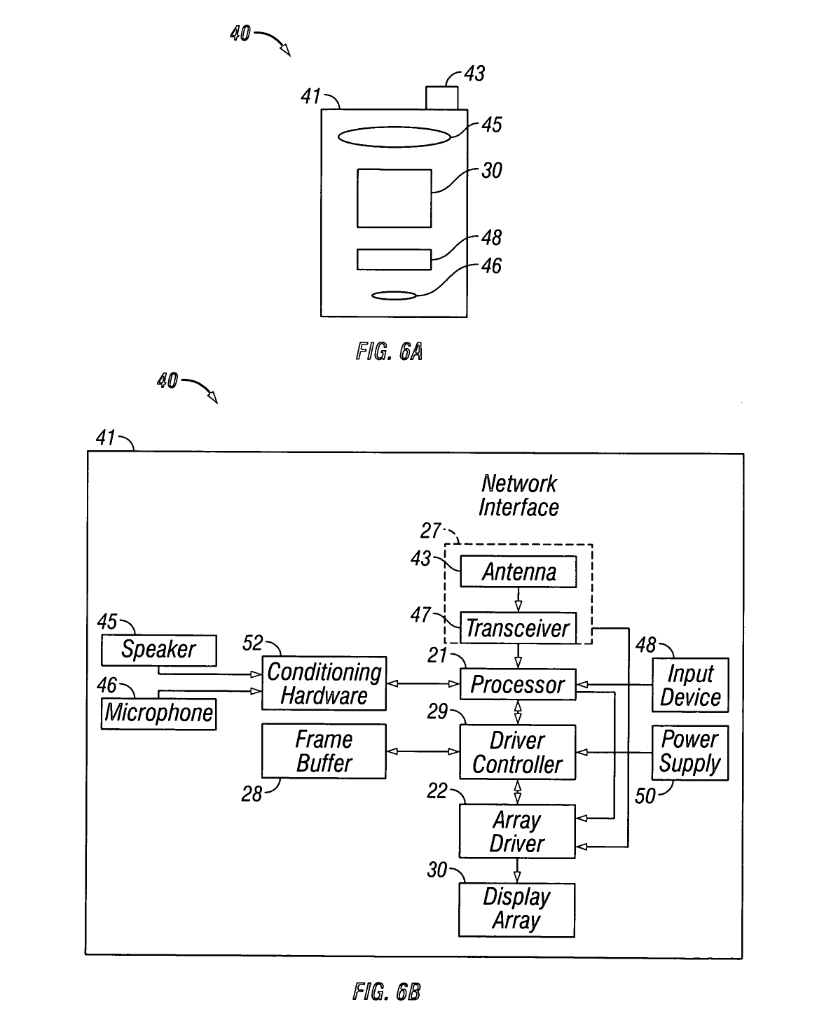

FIGS. 6A and 6B are system block diagrams illustrating an embodiment of a display device 40. The display device 40 can be, for example, a cellular or mobile telephone. However, the same components of display device 40 or slight variations thereof are also illustrative of various types of display devices such as televisions and portable media players.

The display device 40 includes a housing 41, a display 30, an antenna 43, a speaker 45, an input device 48, and a microphone 46. The housing 41 is generally formed from any of a variety of manufacturing processes as are well known to those of skill in the art, including injection molding, and vacuum forming. In addition, the housing 41 may be made from any of a variety of materials, including but not limited to plastic, metal, glass, rubber, and ceramic, or a combination thereof. In one embodiment the housing 41 includes removable portions (not shown) that may be interchanged with other removable portions of different color, or containing different logos, pictures, or symbols.

The display 30 of exemplary display device 40 may be any of a variety of displays, including a bi-stable display, as described herein. In other embodiments, the display 30 includes a flat-panel display, such as plasma, EL, OLED, STN LCD, or TFT LCD as described above, or a non-flat-panel display, such as a CRT or other tube device, as is well known to those of skill in the art. However, for purposes of describing the present embodiment, the display 30 includes an interferometric modulator display, as described herein.

The components of one embodiment of exemplary display device 40 are schematically illustrated in FIG. 6B. The illustrated exemplary display device 40 includes a housing 41 and can include additional components at least partially enclosed therein. For example, in one embodiment, the exemplary display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g. filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 provides power to all components as required by the particular exemplary display device 40 design.

The network interface 27 includes the antenna 43 and the transceiver 47 so that the exemplary display device 40 can communicate with one ore more devices over a network. In one embodiment the network interface 27 may also have some processing capabilities to relieve requirements of the processor 21. The antenna 43 is any antenna known to those of skill in the art for transmitting and receiving signals. In one embodiment, the antenna transmits and receives RF signals according to the IEEE 802.11 standard, including IEEE 802.11(a), (b), or (g). In another embodiment, the antenna transmits and receives RF signals according to the BLUETOOTH standard. In the case of a cellular telephone, the antenna is designed to receive CDMA, GSM, AMPS or other known signals that are used to communicate within a wireless cell phone network. The transceiver 47 pre-processes the signals received from the antenna further manipulated by the processor 21. The transceiver 47 also processes signals received from the processor 21 so that they may be transmitted from the exemplary display device 40 via the antenna 43.

In an alternative embodiment, the transceiver 47 can be replaced by a receiver. In yet another alternative embodiment, network interface 27 can be replaced by an image source, which can store or generate image data to be sent to the processor 21. For example, the image source can be a memory device such as a digital video disc (DVD) or a hard-disc drive that contains image data, or a software module that generates image data.

Processor 21 generally controls the overall operation of the exemplary display device 40. The processor 21 receives data, such as compressed image data from the network interface 27 or an image source, and processes the data into raw image data or into a format that is readily processed into raw image data. The processor 21 then sends the processed data to the driver controller 29 or to frame buffer 28 for storage. Raw data typically refers to the information that identifies the image characteristics at each location within an image. For example, such image characteristics can include color, saturation, and gray-scale level.

In one embodiment, the processor 21 includes a microcontroller, CPU, or logic unit to control operation of the exemplary display device 40. Conditioning hardware 52 generally includes amplifiers and filters for transmitting signals to the speaker 45, and for receiving signals from the microphone 46. Conditioning hardware 52 may be discrete components within the exemplary display device 40, or may be incorporated within the processor 21 or other components.

The driver controller 29 takes the raw image data generated by the processor 21 either directly from the processor 21 or from the frame buffer 28 and reformats the raw image data appropriately for high speed transmission to the array driver 22. Specifically, the driver controller 29 reformats the raw image data into a data flow having a raster-like format, such that it has a time order suitable for scanning across the display array 30. Then the driver controller 29 sends the formatted information to the array driver 22. Although a driver controller 29, such as a LCD controller, is often associated with the system processor 21 as a stand-alone Integrated Circuit (IC), such controllers may be implemented in many ways. They may be embedded in the processor 21 as hardware, embedded in the processor 21 as software, or fully integrated in hardware with the array driver 22.

Typically, the array driver 22 receives the formatted information from the driver controller 29 and reformats the video data into a parallel set of waveforms that are applied many times per second to the hundreds and sometimes thousands of leads coming from the display's x-y matrix of pixels.

In one embodiment, the driver controller 29, array driver 22, and display array 30 are appropriate for any of the types of displays described herein. For example, in one embodiment, driver controller 29 is a conventional display controller or a bi-stable display controller (e.g., an interferometric modulator controller). In another embodiment, array driver 22 is a conventional driver or a bi-stable display driver (e.g., an interferometric modulator display). In one embodiment, a driver controller 29 is integrated with the array driver 22. Such an embodiment is common in highly integrated systems such as cellular phones, watches, and other small area displays. In yet another embodiment, display array 30 is a typical display array or a bi-stable display array (e.g., a display including an array of interferometric modulators).

The input device 48 allows a user to control the operation of the exemplary display device 40. In one embodiment, input device 48 includes a keypad, such as a QWERTY keyboard or a telephone keypad, a button, a switch, a touch-sensitive screen, a pressure- or heat-sensitive membrane. In one embodiment, the microphone 46 is an input device for the exemplary display device 40. When the microphone 46 is used to input data to the device, voice commands may be provided by a user for controlling operations of the exemplary display device 40.

Power supply 50 can include a variety of energy storage devices as are well known in the art. For example, in one embodiment, power supply 50 is a rechargeable battery, such as a nickel-cadmium battery or a lithium ion battery. In another embodiment, power supply 50 is a renewable energy source, a capacitor, or a solar cell, including a plastic solar cell, and solar-cell paint. In another embodiment, power supply 50 is configured to receive power from a wall outlet.

In some implementations control programmability resides, as described above, in a driver controller which can be located in several places in the electronic display system. In some cases control programmability resides in the array driver 22. Those of skill in the art will recognize that the above-described optimization may be implemented in any number of hardware and/or software components and in various configurations.

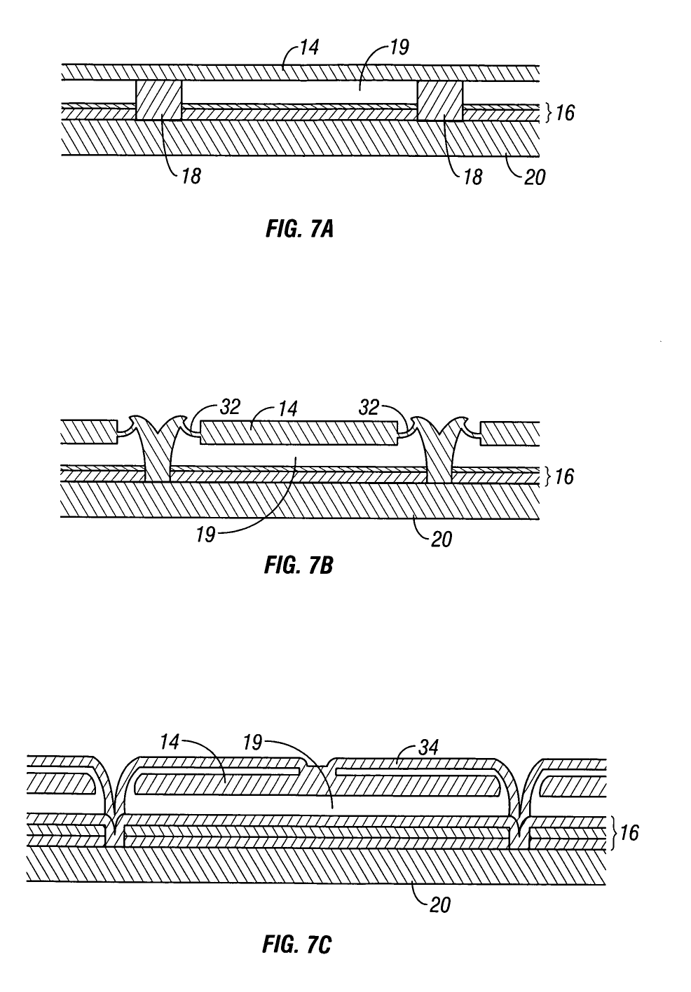

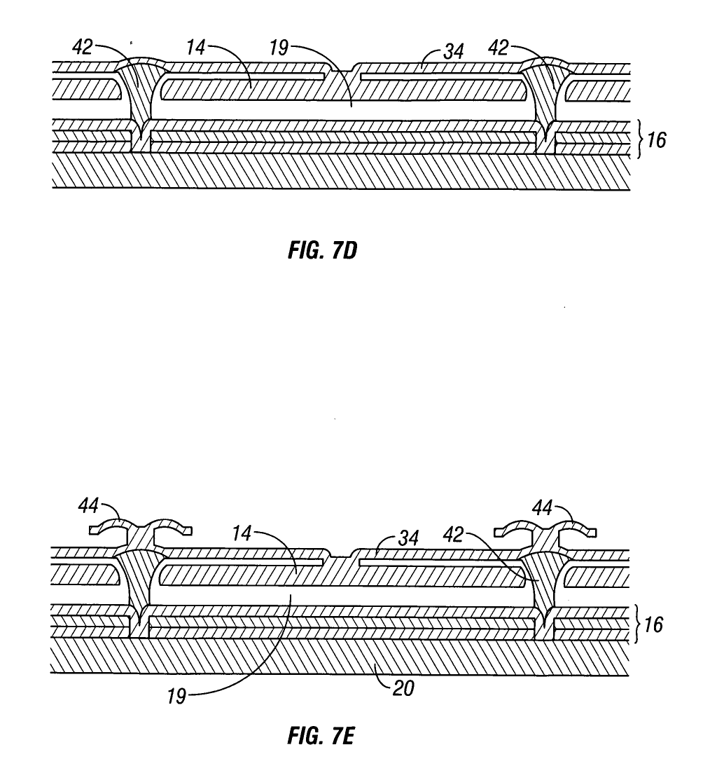

The details of the structure of interferometric modulators that operate in accordance with the principles set forth above may vary widely. For example, FIGS. 7A-7E illustrate five different embodiments of the movable reflective layer 14 and its supporting structures. FIG. 7A is a cross section of the embodiment of FIG. 1, where a strip of metal material 14 is deposited on orthogonally extending supports 18. In FIG. 7B, the moveable reflective layer 14 is attached to supports at the corners only, on tethers 32. In FIG. 7C, the moveable reflective layer 14 is suspended from a deformable layer 34, which may comprise a flexible metal. The deformable layer 34 connects, directly or indirectly, to the substrate 20 around the perimeter of the deformable layer 34. These connections are herein referred to as support posts. The embodiment illustrated in FIG. 7D has support post plugs 42 upon which the deformable layer 34 rests. The movable reflective layer 14 remains suspended over the cavity, as in FIGS. 7A-7C, but the deformable layer 34 does not form the support posts by filling holes between the deformable layer 34 and the optical stack 16. Rather, the support posts are formed of a planarization material, which is used to form support post plugs 42. The embodiment illustrated in FIG. 7E is based on the embodiment shown in FIG. 7D, but may also be adapted to work with any of the embodiments illustrated in FIGS. 7A-7C as well as additional embodiments not shown. In the embodiment shown in FIG. 7E, an extra layer of metal or other conductive material has been used to form a bus structure 44. This allows signal routing along the back of the interferometric modulators, eliminating a number of electrodes that may otherwise have had to be formed on the substrate 20.

In embodiments such as those shown in FIG. 7, the interferometric modulators function as direct-view devices, in which images are viewed from the front side of the transparent substrate 20, the side opposite to that upon which the modulator is arranged. In these embodiments, the reflective layer 14 optically shields the portions of the interferometric modulator on the side of the reflective layer opposite the substrate 20, including the deformable layer 34. This allows the shielded areas to be configured and operated upon without negatively affecting the image quality. Such shielding allows the bus structure 44 in FIG. 7E, which provides the ability to separate the optical properties of the modulator from the electromechanical properties of the modulator, such as addressing and the movements that result from that addressing. This separable modulator architecture allows the structural design and materials used for the electromechanical aspects and the optical aspects of the modulator to be selected and to function independently of each other. Moreover, the embodiments shown in FIGS. 7C-7E have additional benefits deriving from the decoupling of the optical properties of the reflective layer 14 from its mechanical properties, which are carried out by the deformable layer 34. This allows the structural design and materials used for the reflective layer 14 to be optimized with respect to the optical properties, and the structural design and materials used for the deformable layer 34 to be optimized with respect to desired mechanical properties.

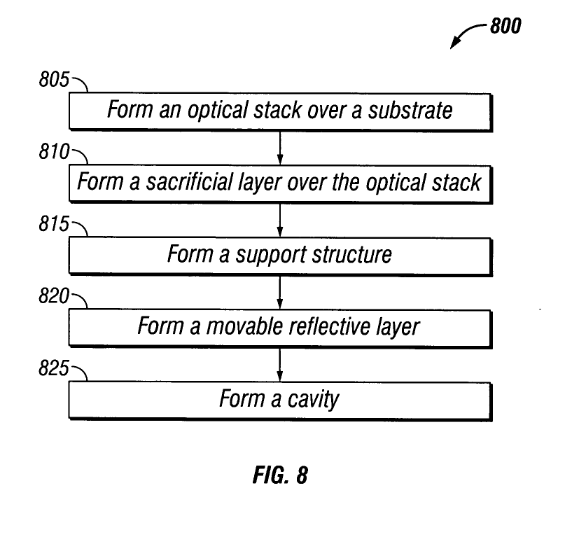

FIG. 8 illustrates certain steps in an embodiment of a manufacturing process 800 for an interferometric modulator. Such steps may be present in a process for manufacturing, e.g., interferometric modulators of the general type illustrated in FIGS. 1 and 7, along with other steps not shown in FIG. 8. With reference to FIGS. 1, 7 and 8, the process 800 begins at step 805 with the formation of the optical stack 16 over the substrate 20. The substrate 20 may be a transparent substrate such as glass or plastic and may have been subjected to prior preparation step(s), e.g., cleaning, to facilitate efficient formation of the optical stack 16. As discussed above, the optical stack 16 is electrically conductive, partially transparent and partially reflective, and may be fabricated, for example, by depositing one or more of the layers onto the transparent substrate 20. In some embodiments, the layers are patterned into parallel strips, and may form row electrodes in a display device. In some embodiments, the optical stack 16 includes an insulating or dielectric layer that is deposited over one or more metal layers (e.g., reflective and/or conductive layers).

The process 800 illustrated in FIG. 8 continues at step 810 with the formation of a sacrificial layer over the optical stack 16. The sacrificial layer is later removed (e.g., at step 825) to form the cavity 19 as discussed below and thus the sacrificial layer is not shown in the resulting interferometric modulator 12 illustrated in FIG. 1. The formation of the sacrificial layer over the optical stack 16 may include deposition of a XeF₂-etchable material such as molybdenum or amorphous silicon, in a thickness selected to provide, after subsequent removal, a cavity 19 having the desired size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 800 illustrated in FIG. 8 continues at step 815 with the formation of a support structure e.g., a post 18 as illustrated in FIGS. 1 and 7. The formation of the post 18 may include the steps of patterning the sacrificial layer to form a support structure aperture, then depositing a material (e.g., a polymer oxide) into the aperture to form the post 18, using a deposition method such as PECVD, thermal CVD, or spin-coating. In some embodiments, the support structure aperture formed in the sacrificial layer extends through both the sacrificial layer and the optical stack 16 to the underlying substrate 20, so that the lower end of the post 18 contacts the substrate 20 as illustrated in FIG. 7A. In other embodiments, the aperture formed in the sacrificial layer extends through the sacrificial layer, but not through the optical stack 16. For example, FIG. 7D illustrates the lower end of the support post plugs 42 in contact with the optical stack 16.

The process 800 illustrated in FIG. 8 continues at step 820, with the formation of a movable reflective layer such as the movable reflective layer 14 illustrated in FIGS. 1 and 7. The movable reflective layer 14 may be formed by employing one or more deposition steps, e.g., reflective layer (e.g., aluminum, aluminum alloy) deposition, along with one or more patterning, masking, and/or etching steps. As discussed above, the movable reflective layer 14 is typically electrically conductive, and may be referred to herein as an electrically conductive layer. Since the sacrificial layer is still present in the partially fabricated interferometric modulator formed at step 820 of the process 800, the movable reflective layer 14 is typically not movable at this stage. A partially fabricated interferometric modulator that contains a sacrificial layer may be referred to herein as an “unreleased” interferometric modulator.

The process 800 illustrated in FIG. 8 continues at step 825 with the formation of a cavity, e.g., a cavity 19 as illustrated in FIGS. 1 and 7. The cavity 19 may be formed by exposing the sacrificial material (deposited at step 810) to an etchant. For example, an etchable sacrificial material such as molybdenum or amorphous silicon may be removed by dry chemical etching, e.g., by exposing the sacrificial layer to a gaseous or vaporous etchant, such as vapors derived from solid xenon difluoride (XeF₂) for a period of time that is effective to remove the desired amount of material, typically selectively relative to the structures surrounding the cavity 19. Other etching methods, e.g. wet etching and/or plasma etching, may also be used. Since the sacrificial layer is removed during step 825 of the process 800, the movable reflective layer 14 is typically movable after this stage. After removal of the sacrificial material, the resulting fully or partially fabricated interferometric modulator may be referred to herein as a “released” interferometric modulator.

The performance of MEMS devices in general and interferometric modulators in particular, may be adversely affected by a condition known in the art as stiction. With reference to FIG. 1, stiction can cause, for example, the actuated movable layer 14b to remain in contact with the optical stack 16b, even in the presence of a restoring force that would be expected to return the movable layer 14b to the unactuated position. Stiction occurs when the total of several adhesion forces, arising from various adhesion mechanisms, are greater than the restoring force. The restoring force includes the combined mechanical tension forces in the actuated movable layer. Since surface forces become more significant with decreasing device dimensions, and restoring forces shrink with decreasing device dimensions, stiction is a concern for MEMS devices including interferometric modulators.

Adhesion forces may arise from several mechanisms including, for example, capillary forces, van der Waals interactions, chemical bonds and trapped charges. Adhesion forces due to all of these mechanisms, in varying degrees, depend on the contact area and surface separation between the various movable and stationary layers when in the actuated state. Embodiments provide methods of manufacturing MEMS devices with lower contact area and/or larger surface separation, thereby resulting in lower adhesion forces and more favorable performance due to less stiction.

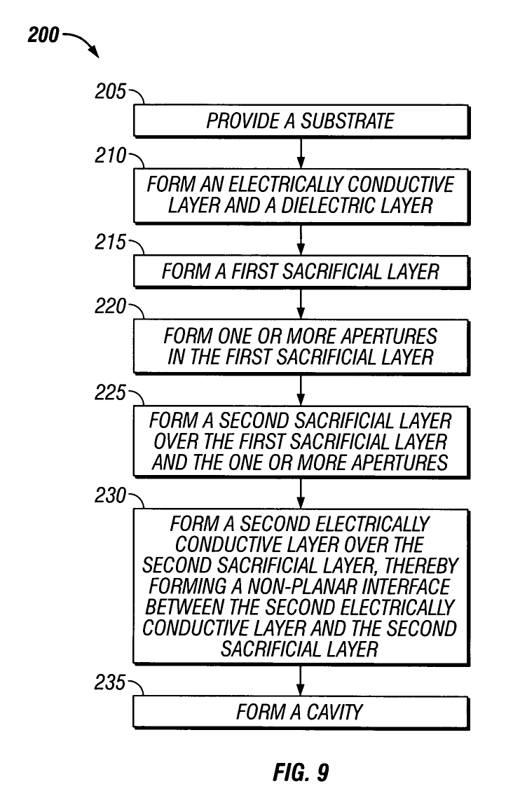

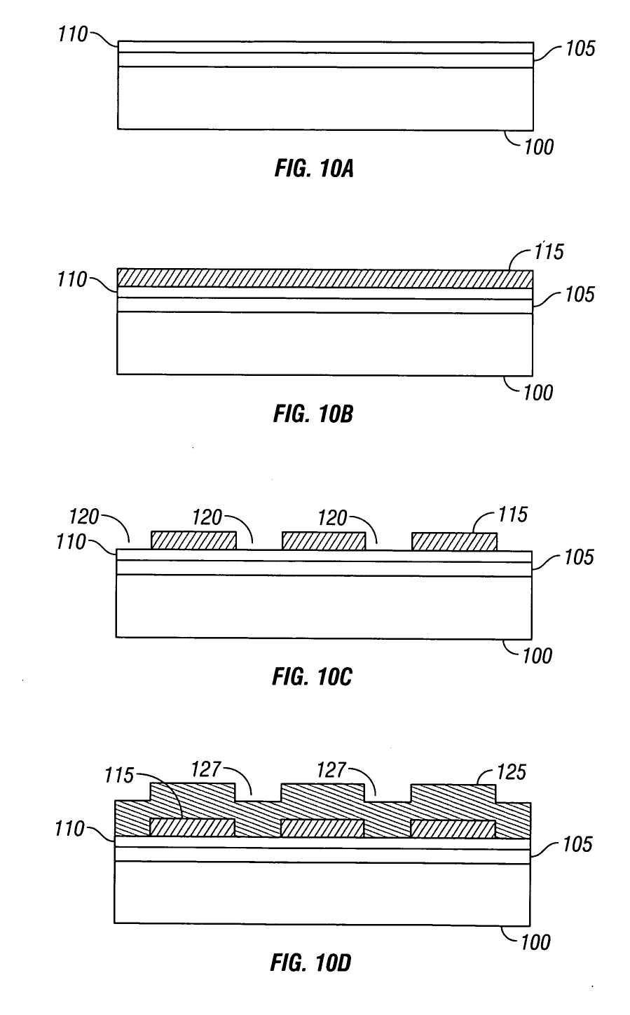

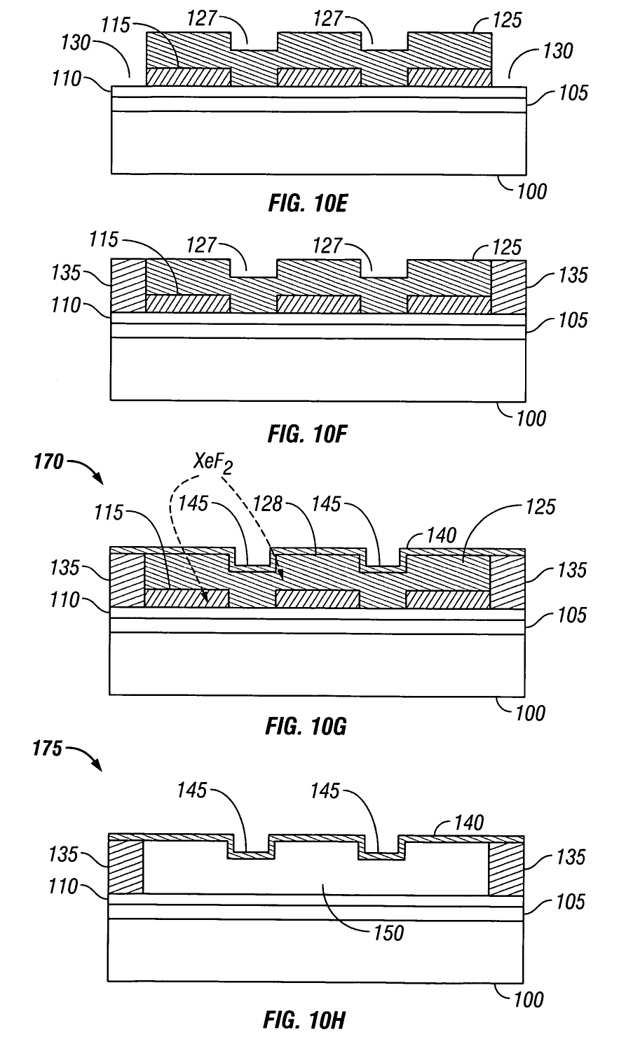

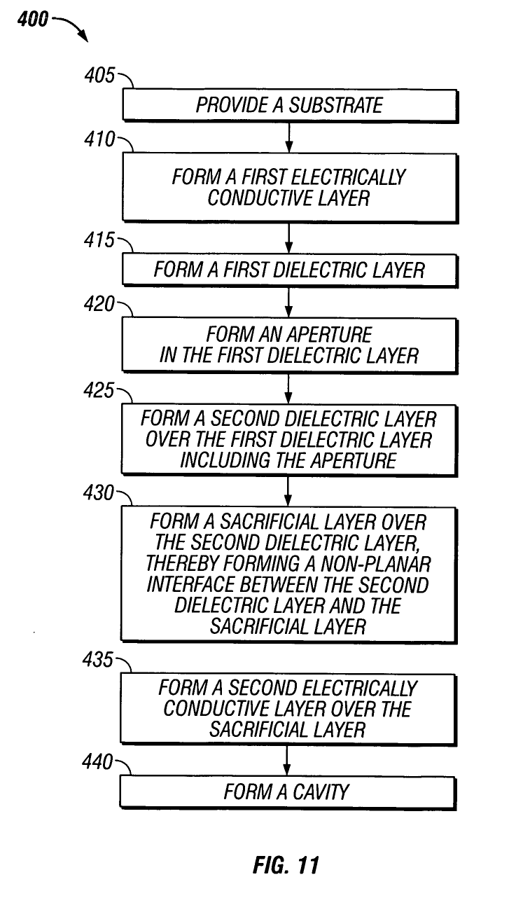

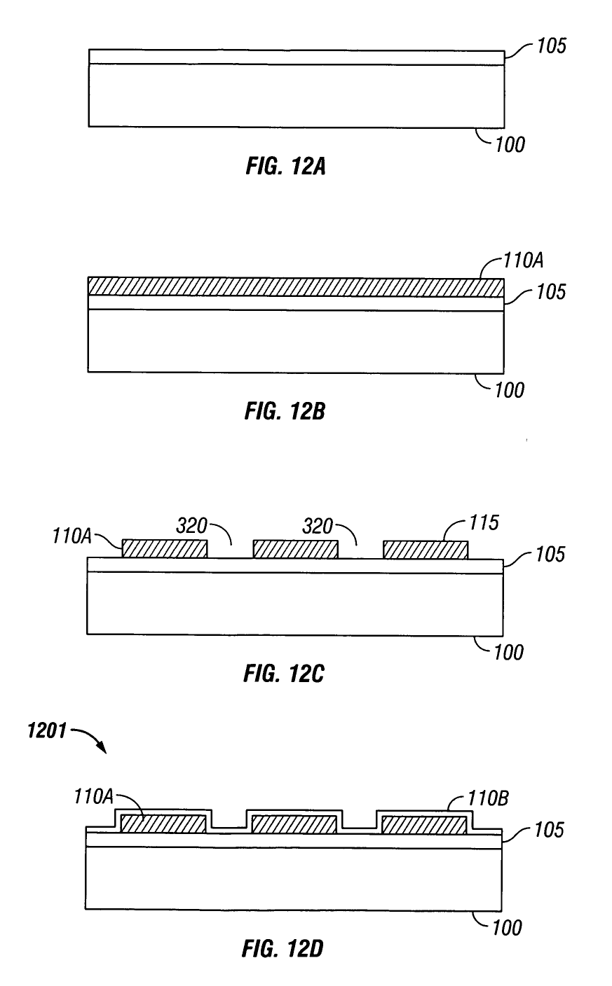

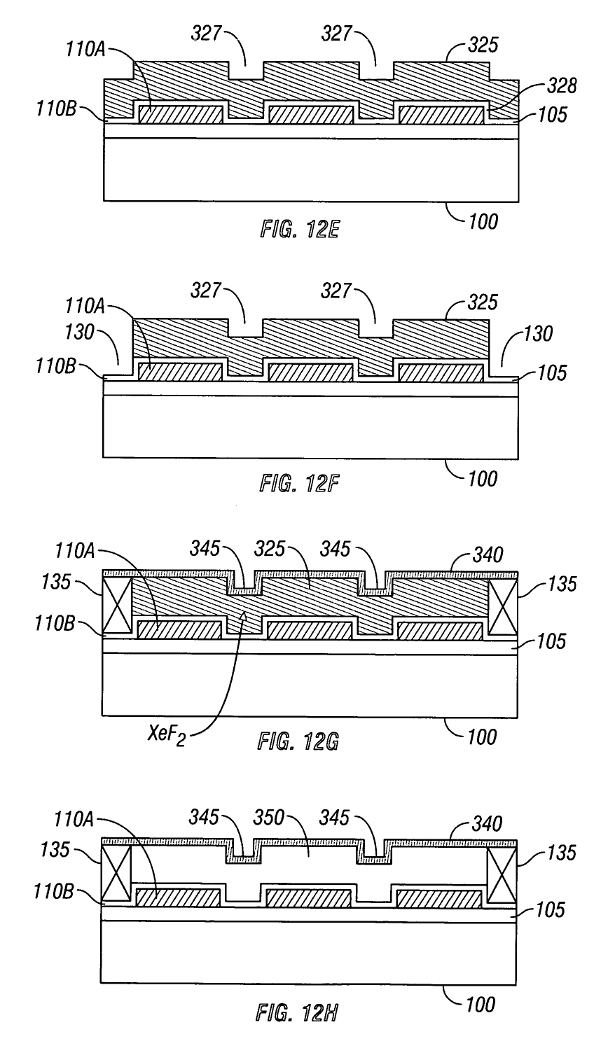

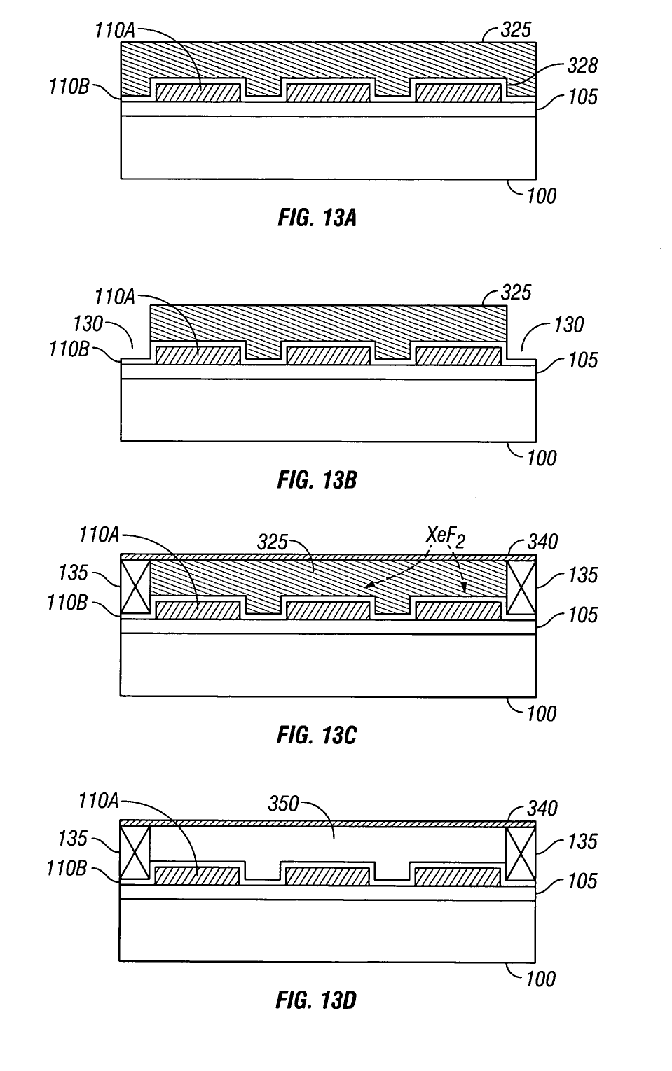

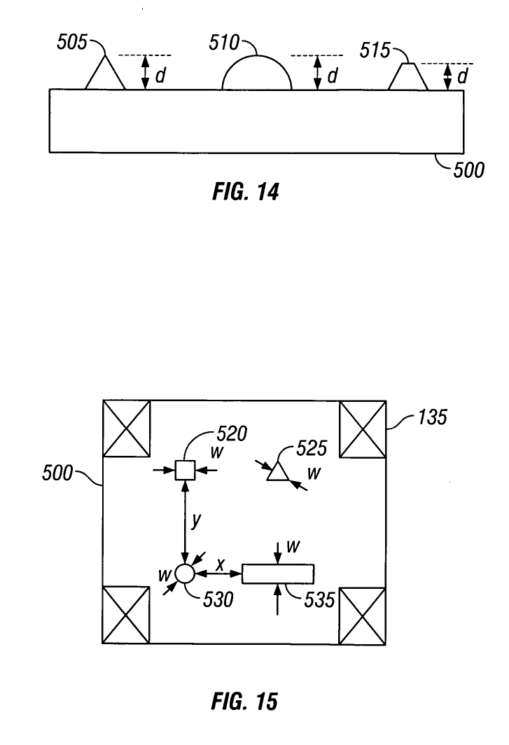

FIG. 9 is a flow diagram illustrating certain steps in an embodiment of a method of making a MEMS device. Such steps may be present in a process for manufacturing, e.g., interferometric modulators of the general type illustrated in FIGS. 1 and 7, along with other steps not shown in FIG. 9. FIGS. 10A through 10H schematically illustrate an embodiment of a method for fabricating a MEMS device using conventional semiconductor manufacturing techniques such as photolithography, deposition, masking, etching (e.g., dry methods such as plasma etch and wet methods), etc. Deposition includes “dry” methods such as chemical vapor deposition (CVD, including plasma-enhanced CVD and thermal CVD) and PVD (e.g., sputtering), and wet methods such as spin coating. With reference to FIGS. 9 and 10, the process 200 begins at step 205 where a substrate 100 is provided. In one embodiment, the substrate 100 may comprise any transparent material such as glass or plastic.

The process 200 continues to step 210 with the formation of a first electrically conductive layer 105 on the substrate 100 as shown in FIG. 10A. The first electrically conductive layer 105 can be a single layer structure or multiple sub-layer structure as described above. In a single layer structure where the layer 105 functions as both electrode and mirror, the layer 105 is formed by deposition of an electrically conductive material on the substrate 100. The first electrically conductive layer 105 may be formed into electrodes through subsequent patterning and etching not shown in FIGS. 9 or 10. The first electrically conductive layer 105 may be a metal or a semiconductor (such as silicon) doped to have the desired conductivity. In one embodiment (not shown in FIG. 10), the first electrically conductive layer 105 is a multilayer structure comprising a transparent conductor (such as indium tin oxide) and a primary mirror or partially reflective layer (such as chromium).

Step 210 also includes the formation of a dielectric layer 110 over at least a portion of the electrically conductive layer 105. The dielectric layer 110 may be formed by known deposition methods, preferably CVD. The dielectric layer may comprise insulating materials such as silicon oxide and/or aluminum oxide. The dielectric layer 110 serves to insulate the first electrically conductive layer 105 from an electrically conductive movable layer (such as movable layer 14 of FIGS. 1 and 7) in an interferometric modulator.

The process 200 continues at step 215 with the formation of a first sacrificial layer 115 as shown in FIG. 10B. The first sacrificial layer 115 may comprise a material etchable by XeF₂, preferably molybdenum. The first sacrificial layer 115 is then patterned and etched in a step 220 to form one or more apertures 120 as shown in FIG. 10C. The apertures 120 preferably extend entirely through the first sacrificial layer 115 to the dielectric layer 110. In one embodiment, the dielectric layer 110 comprises a material (such as an aluminum oxide) that is not etchable by XeF₂. Deposition methods such as chemical vapor deposition (CVD, including plasma-enhanced CVD and thermal CVD) and sputtering, can be used to deposit the first sacrificial layer 115.

The process 200 continues at step 225 with the formation of a second sacrificial layer 125 over the first sacrificial layer 115 and the apertures 120. Since the second sacrificial layer 125 is formed over the apertures 120, the upper surface of the layer 125 will generally conform to the shape of the apertures (shown as depressions 127 in FIG. 10D), though generally not exactly, depending on the deposition method used. The second sacrificial layer 125 may comprise the same or a different material than the first sacrificial layer 115. Deposition methods such as CVD, sputtering or spin coating may be used in forming the second sacrificial layer 125.

In one embodiment, one or more support structure apertures 130, as shown in FIG. 10E, are formed in the second sacrificial layer and support structure material is deposited into the apertures 130 forming support structures 135 as shown in FIG. 10F. The support structures 135 may comprise a non-conductive material. The location of the support structure apertures 130 may be in either or both of the sacrificial layers 115 and 125.

The process 200 continues at step 230 with the formation of a second electrically conductive layer 140 over the second sacrificial layer 125 and, in the illustrated embodiment, over the support structures 135. Due to the presence of the depressions 127 in the second sacrificial layer 125, a non-planar interface 128, characterized by bumps 145 as shown in FIG. 10G, is formed between the second sacrificial layer 125 and the second electrically conductive layer 140. In one embodiment, the second electrically conductive layer comprises a movable layer such as movable layer 14 of an interferometric modulator as shown in FIGS. 1 and 7. Since the sacrificial layer 125 is still present at this stage of the process 200, the movable layer is typically not yet movable. A partially fabricated MEMS device 170, e.g. a partially fabricated interferometric modulator, that contains sacrificial layers (the layers 115 and 125 in this embodiment) may be referred to herein as an “unreleased” MEMS device. The second electrically conductive layer 140 may comprise a metal (e.g. aluminum or aluminum alloy). Forming the electrically conductive layer 140 in step 230 may include one or more deposition steps as well as one or more patterning or masking steps.

The process 200 continues at step 235 where the first sacrificial layer 115 and the second sacrificial layer 125 are removed (e.g., by etching) to form a cavity 150 as shown in FIG. 10H. The removal of the sacrificial layers can be accomplished, for example, by exposure to an etchant such as XeF₂ (as depicted in FIG. 10G), F₂ or HF alone or in combination. In a preferred embodiment, substantially all of the sacrificial layers 115 and 125 are removed in the etching process. In one embodiment, the cavity 150 is an interferometric cavity between an optical stack (comprising the electrically conductive layer 105 and the dielectric layer 110) and the conductive movable layer 140. After formation of the cavity 150, the resulting MEMS device, the interferometric modulator 175, is in a “released” state.

The bumps 145 formed in the second electrically conductive layer 140 serve to reduce the area of contact between the layer 140 and the layer 110 when the interferometric modulator 175 is in the actuated position, thereby preventing stiction as discussed above. Details of bump configurations, aperture configurations and dimensions are discussed below. In some embodiments, the process 200 may include additional steps and the steps may be rearranged from the illustrations of FIGS. 9 and 10.

FIG. 11 is a flow diagram illustrating certain steps in another embodiment of a method of making an interferometric modulator. Such steps may be present in a process for manufacturing, e.g., interferometric modulators of the general type illustrated in FIGS. 1 and 7, along with other steps not shown in FIG. 11. FIGS. 12A through 12H schematically illustrate an embodiment of a method for fabricating an interferometric modulator. The process shown in FIG. 11 and 12 illustrates patterning of a first dielectric layer to form apertures. The dielectric layer is used as example only and other layers (e.g. any layers of the dielectric stack 16 of an interferometric modulator as discussed above and shown in FIGS. 1 and 7) could also be used. With reference to FIGS. 11 and 12, the process 400 begins at step 405 where a substrate 100 is provided. Step 405 is similar to step 205 in the process 200 discussed above.

The process 400 continues at step 410 with the formation of a first electrically conductive layer 105 on the substrate 100 as shown in FIG. 12A. In this embodiment step 410 is similar to step 210 of the process 200 discussed above. As discussed above, the first electrically conductive layer 105 can be a single layer structure or a multiple sub-layer structure as described above. In a single layer structure where the layer 105 functions as both electrode and mirror, the layer 105 is formed by deposition of an electrically conductive material on the substrate 100. The first electrically conductive layer 105 may be formed into electrodes through subsequent patterning and etching steps not shown in FIGS. 11 or 12. The first electrically conductive layer 105 may be a metal or a semiconductor (such as silicon) doped to have the desired conductivity. In one embodiment (not shown in FIG. 12), the first electrically conductive layer 105 is a multilayer structure comprising a transparent conductor (such as indium tin oxide) and a primary mirror or partially reflective layer (such as chromium).

The process 400 continues at step 415 with the formation of a first dielectric layer 110A over at least a portion of the electrically conductive layer 105 as shown in FIG. 12B. The first dielectric layer 110A may be formed by known deposition methods, preferably CVD. The first dielectric layer 110A may comprise insulator materials such as silicon oxide(s) and/or aluminum oxide(s). The first dielectric layer 110A can be formed by, e.g., CVD or sputtering.

Continuing to step 420, one or more apertures 320, as shown in FIG. 12C, are formed in the first dielectric layer 110A resulting in a discontinuous first dielectric layer 110A. Formation of the apertures 320 may be accomplished by patterning and etching techniques known to those of skill in the art. The apertures 320 preferably extend entirely through the first dielectric layer 110A to the electrically conductive layer 105. Details on the preferred dimensions of the first dielectric layer 110A and the apertures 320 are discussed below. In one embodiment the apertures 320 define the distances between bumps or dimples formed by the remaining first dielectric layer 110A.

The process 400 continues at step 425 with the formation of a second dielectric layer 110B over the first dielectric layer 110A. Unlike the discontinuous first dielectric layer 110A, the second layer 110B is continuous over at least a portion of the discontinuous dielectric layer 110A and the one or more apertures 320. Due to the apertures 320 formed in the first dielectric layer 110A, the second dielectric layer 110B has a non-planar surface conforming generally to the shape of the apertures 320 and the bumps formed by the remaining first dielectric layer 110A as shown in FIG. 12D. The first dielectric layer 110A and the second dielectric layer 110B may be comprised of the same or different dielectric materials. The dielectric layers 110A, 110B serve to insulate the first electrically conductive layer 105 from an electrically conductive movable layer (such as movable layer 14 of FIGS. 1 and 7) in an interferometric modulator. In an alternative embodiment, the electrically conductive layer 105 or another layer (e.g., a metal layer, an electrically conductive layer, and/or a reflective layer) could be patterned to form the apertures which could propagate upwards through layers including the second dielectric layer 110B (the first dielectric layer 110A could be omitted in this embodiment). In this embodiment, the second dielectric layer 110B is continuous over the lower patterned layer containing the apertures. In this embodiment, the lower layer may comprise an electrically conductive material but the dielectric layer 110B being continuous may minimize or eliminate the risk of a short circuit of the stationary and movable electrically conductive layers (e.g., between the layers 16, 14 shown in FIG. 1).

The process 400 continues at step 430 with the formation of a sacrificial layer 325 over the second dielectric layer 110B. Since the sacrificial layer 325 is formed over the depressions formed in the second dielectric layer due to the apertures 320, the upper surface of layer 325 will generally conform to the shape of the lower layer depressions (shown as depressions 327 in FIG. 12E), though generally not exactly. A non-planar interface 328 is formed between the second dielectric layer 110B and the sacrificial layer 325. In one embodiment, the sacrificial layer 325 is comprised of molybdenum. Deposition methods such as CVD, sputtering or spin coating may be used in forming the sacrificial layer 325.

In one embodiment, support structure apertures 130, as shown in FIG. 12F, are formed in the sacrificial layer 325 and support structure material is deposited into the apertures 130 forming support structures 135 as shown in FIG. 12G. The support structures 135 may comprise a non-conductive material.

The process 400 continues at step 435 with the formation of a second electrically conductive layer 340 over the sacrificial layer 325 as shown in FIG. 12G. In this embodiment the second electrically conductive layer comprises one or more bumps 345 formed in the same general shape as the depressions 327 in the sacrificial layer 325. Deposition methods such as CVD, sputtering or spin coating may be used in forming the second electrically conductive layer 340. In one embodiment, the second electrically conductive layer 340 comprises a movable layer such as the movable layer 14 of an interferometric modulator as shown in FIGS. 1 and 7. As discussed above, since the sacrificial layer 325 is still present at this stage of the process 400, the movable layer is typically not yet movable in the unreleased interferometric modulator. The second electrically conductive layer 340 may comprise a metal (e.g. aluminum or aluminum alloy). Forming the electrically conductive layer 340 in step 435 may include one or more deposition steps as well as one or more patterning or masking steps.

The process 400 continues at step 440 where the sacrificial layer 325 is removed (e.g., by etching) to form a cavity 350 as shown in FIG. 12H. The removal of the sacrificial layer 325 may be accomplished by exposure to an etchant such as XeF₂ (as depicted in FIG. 12G), F₂ or HF alone or in combination. In a preferred embodiment, substantially all of the sacrificial layer 325 is removed in the etching process. In one embodiment, the cavity 350 is an interferometric cavity between an optical stack (comprising the electrically conductive layer 105 and the dual layer dielectric layer 110A, 110B) and the conductive movable layer 340. After formation of the cavity 350, the interferometric modulator device is in a “released” state.

Due to non-exact replication of contour shapes during the deposition steps discussed above, the bumps 345 in the second electrically conductive layer 340 will generally not fit exactly into the depressions formed in the second dielectric layer 110B. Thus, stiction may be reduced during actuation because the contact area is reduced and surface separation is increased.

FIGS. 13A through 13D schematically illustrate another embodiment of a method for fabricating a MEMS device. The method illustrated in FIG. 13 may be performed starting with the partially fabricated MEMS device 1201, after the formation of the second dielectric layer 110B, as shown in FIG. 12D. The method illustrated in FIGS. 13A through 13D may be carried out as generally described above with respect to FIGS. 12E through 12H, except that in this embodiment, the sacrificial layer 325 is planarized, thereby removing or preventing the formation of the depressions 327 before the second electrically conductive layer 340 is deposited at step 435 of FIG. 11 as illustrated in FIG. 13D. The result is a substantially planar second electrically conductive layer 340. Since the second dielectric layer 110B is non-planar due to the voids 320 formed in the first dielectric layer 110A, the contact area during actuation is still reduced, thereby reducing the adhesion forces and reducing the likelihood of stiction. Planarizing may be accomplished by chemical mechanical polishing (CMP) and/or by forming the sacrificial layer 325 by spin coating. When using CMP for planarizing the sacrificial layer 325, precautions should be taken to provide a sufficient depth of sacrificial material in the sacrificial layer 325 to provide a desired thickness of the sacrificial layer 325 after removal of some of the sacrificial material during CMP. The remaining sacrificial layer 325 will define the depth of the cavity 150 (shown in FIG. 13D) that is formed during release of the MEMS device at step 440 of FIG. 11.

In an alternative embodiment, the electrically conductive layer 105 or another layer (e.g., a metal layer, an electrically conductive layer, and a reflective layer) could be patterned to form the apertures which could propagate upwards through layers including the second dielectric layer 110B (the first dielectric layer 110A could be omitted in this embodiment). In this embodiment, a first layer is formed and at least one aperture is formed in the first layer. A second layer is then formed over the first layer so that the apertures are substantially propagated upwards into the second layer, e.g., by conformal deposition of the second layer onto the first layer. In some embodiments, the first layer is thinner than the second layer, preferably the first layer has a thickness of about 500 angstroms or less, more preferably about 10 angstroms to about 500 angstroms. The first and second layers may both comprise similar materials, e.g. both may comprise a metal or both may comprise a dielectric material. The first and second layers may comprise different materials. Either the first or the second layers may comprise materials such as, for example, a metal, a dielectric, a transparent material, an electrically conductive layer or a sacrificial material.

The methods discussed above are used to fabricate non-planar surface formations such as bumps, depressions, dimples etc. The embodiments shown in FIGS. 10, 12 and 13 have substantially flat upper surfaces, but this is not necessary and may not be desirable. For example, FIG. 14 shows a side cross sectional view illustrating alternative embodiments of non-planar surface formations that may be used to minimize contact area and/or provide increased separation distance to prevent stiction. The various non-planar surface formations of FIG. 14 include a triangular cross section 505, a semicircular (or elliptical) cross section 510 and a polygon 515. The surface formations 505, 510 and 515 all have a smaller surface area on the top, for a given base dimension, than the rectangular cross sections shown in FIGS. 10, 12 and 13 (the top portion being the portion that will contact another surface moving toward the substrate 500). Therefore, these alternative formations may be more desireable for reducing stiction than the rectangular bumps shown in FIGS. 10 and 12. In one embodiment, isotropic etching may be used to form cross sections such as those shown in FIG. 14.

The surface formations 505, 510 and 515 exemplified in FIG. 14 are characterized by a height dimension labeled “d” in FIG. 14. The height “d” is measured perpendicular to the substrate 500 as shown in FIG. 14. In the case of surface formations formed by forming a layer over another layer containing apertures, or depressions caused by lower formed apertures, the height of the non-planar surface formation will be determined by the depth of the aperture or depression as discussed above. Various surface formations (such as the formations 505, 510, and 515) may be referred to herein as dimples, and may be characterized by a height “d” as shown in FIG. 14. The shapes of the dimples 505, 510 and 515 are only examples and other shapes may be used.

FIG. 15 shows a top cross sectional view of alternative embodiments of non-planar surface formations, e.g. dimples, on a MEMS device, e.g. an interferometric modulator. The interferometric modulator is formed on the substrate 500 and has four support structures 135, positioned in the corners. The interferometric modulator is shown having four dimples, a square dimple 520, a triangular dimple 525, a generally circular dimple 530 and an oblong rectangular dimple 535. Each of the dimples 520, 525, 530, and 535 is characterized by a minimum cross sectional dimension “w” as measured parallel to the substrate 500. The shapes of the dimples 520, 525, 530 and 535 are only examples and other shapes may be used. The distances between the dimples are indicated by “y” between dimple 520 and dimple 530, and by “x” between dimple 530 and dimple 535. The distances “x” and “y” will be referred to herein as the separation distance between dimples. Preferred dimple configurations and dimensions (utilizing the dimple height, the dimple cross sectional dimension, and the separation distance as discussed above and shown in FIGS. 14 and 15) will now be discussed in relation to various adhesion force characteristics as well as patterning and etching capabilities.

As discussed above, adhesion forces may arise from several mechanisms including, for example, capillary forces, van der Waals interactions, chemical bonds and trapped charges. Adhesion forces due to all of these mechanisms, in varying degrees, depend on the contact area and surface separation between the various movable and stationary layers when in the actuated state. Adhesion forces can be classified into two types, short range and long range. Short range adhesion is affected by the contact area between two surfaces. For a given bump or dimple contact area, short range adhesion is mainly affected by the distance between the bumps or dimples and the cross sectional area of the dimple. Thus, short range adhesion is roughly proportional to the contacting area ratio, or as it is also known, the fill factor (the fraction of total surface area in contact). Long range adhesion is affected mainly by the height of the bumps as measured perpendicular to the contact surfaces. Long range adhesion acts over separation distances in the range of about 200 angstroms to about 300 angstroms. Capillary forces are one example of long range adhesion forces.

As two hydrophilic surfaces approach each other in a humid environment, the liquid undergoes capillary condensation as soon as the separation distance equals:
d=2rₖ cos θ (1)
where rₖ is the Kelvin radius given by:

$${r}_{k} = \frac{γ v}{RT log ( P \text{/} {P}_{s} )} \qquad ( 2 )$$

where γ is the surface tension of water, v is the molar volume and P/Pₛ is the relative vapor pressure. For example, γv/RT=0.54 nanometers for water at 20° C. In one embodiment of an interferometric modulator, aluminum and/or aluminum oxide surfaces contact at an angle in a range of about 7 to about 10 degrees, while the relative humidity inside the package is in a range of about 0.3% to about 3% (or P/Ps in a range of about 0.1% to about 0.01%), resulting in a separation below which water condensation occurs (using equations (1) and (2) above) for which d is equal to about 1.8 angstroms. Thus, any dimple height significantly larger than this distance will result in capillary force reduction proportional to the area ratio of the dimple surface contact area ratio.

Van der Waals interactions result from the interaction between the instantaneous dipole moments of atoms. These attraction forces are quite strong at the asperity contacts due to the surface roughness. However, these forces may be significant even at non-contacting surface asperities if the surface separation is very small. In one embodiment of interferometric modulators, the surface separation between the actuated movable surface and the stationary surface is in a range of about 100 angstroms to about 200 angstroms. Therefore, dimples larger than this range have the potential for reducing the van der Waals interaction adhesion forces.

Chemical bonds are due to chemical interactions between molecules at the asperity contacts of the contact area or across very small gaps. Relatively large gaps, e.g. on the order of about 100 angstroms will eliminate the adhesion forces due to chemical bonds thus reducing the area producing chemical bond forces to the area of the dimples.

Electrostatic forces due to trapped charges in the various layers of the stationary and movable layers may be present. Since these forces are inversely proportional to the square of the surface separation, reducing the contact area and increasing the separation distance with increased dimple height will both serve to reduce the electrostatic adhesion forces.

All the adhesion forces discussed above reduce with greater separation. The preferred minimum amount of separation is mainly a function of the root mean square (RMS) of surface roughness of the deposited materials. RMS surface roughness in one embodiment may be about 10 to about 20 angstroms. RMS surface roughness may be measured in various ways, preferably by atomic force microscopy. In an embodiment of interferometric modulators discussed above, where the surface separation between the actuated movable surface and the stationary surface is in a range of about 100 angstroms to about 200 angstroms, dimples in excess of this range will reduce the adhesion forces. The preferred maximum dimple height is mainly a function of not affecting the optical (in the case of interferometric modulators) or electrical properties of the interferometric modulator. Optical properties may exhibit optical degradation with dimples of about 500 angstroms in height or taller. Therefore, a dimple height in a range of about 100 angstroms to about 500 angstroms is preferable for the embodiment of the interferometric modulator discussed here.

The dimples should be as small in cross sectional dimension as possible, since the contact area will be minimized for a given dimple separation distance. The cross sectional width of dimples created by masking and patterning techniques known in the art are limited by the photolithography limits of the masking technology being used to form the dimples (or the separation of apertures in the case of forming dimples in the lower stationary levels as shown in FIGS. 11, 12 and 13 above). Typical photolithography limits, permit details on the order of a range from about 2 micrometers to about 5 micrometers. Therefore, the typical minimum sized dimples (in terms of a cross sectional dimension as measured parallel to the substrate) are in a range of about 2 micrometers to about 5 micrometers. Improvements in photolithography below this range would allow smaller dimples than this.

The lateral separation distance (as measured parallel to the substrate) between dimples will determine the contact area reduction achieved and will therefore determine the reduction in adhesion forces. One would like the dimples to be as far apart as possible, however mechanical properties of the movable elements in MEMS devices or interferometric modulators may limit the lateral distance. Bending of the mechanical/movable layer may cause local collapse and result in contact of a significant surface area. Therefore, it is desirable to design the separation distance, in one embodiment, to prevent local collapse of a mechanical/movable element. Finite element analysis and electrostatic pressure calculations, known to those of skill in the art, may be used to estimate the maximum separation distance to prevent collapse. These calculations depend on the stiffness of the layer (or layers in case of two or more bendable layers) being supported by the dimples. Separation distances of up to about 100 micrometers may be obtained for some mechanical/movable elements of the various interferometric modulators as shown in FIG. 7. The preferred smallest separation distance is typically on the order of about 4 micrometers in order to obtain a reasonable area reduction for the smallest dimples that could be fabricated by photolithography (about 2 micrometers across). Therefore, in a preferred embodiment, the separation distance of the dimples created by the fabrication methods discussed above (or the width of the formed aperture separating the dimples) is in the range of about 4 micrometers to about 100 micrometers.

An embodiment of an interferometric modulator includes first means for reflecting light, second means for reflecting light, wherein the second means for reflecting light is capable of moving towards the first reflecting means in an actuated state, means for reducing stiction between the first reflecting means and the second reflecting means in the actuated state, while simultaneously not substantially affecting optical properties, and means for supporting the second reflecting means. With reference to FIG. 12H, aspects of this embodiment include where the first reflecting means is a partially reflective layer such as the conductive layer 105, where the second reflecting means is a movable reflective layer such as the second electrically conductive layer 340, where the stiction-reducing means is the continuous dielectric layer 110B over the discontinuous dielectric layer 110A, and where the supporting means is the support post 135. In one aspect of this embodiment, the depth of the discontinuous dielectric layer 110A is in a range of about 100 angstroms to about 500 angstroms as measured perpendicular to the first reflecting means.

While the above detailed description has shown, described, and pointed out novel features of the invention as applied to various embodiments, it will be understood that various omissions, substitutions, and changes in the form and details of the device or process illustrated may be made by those skilled in the art without departing from the spirit of the invention. As will be recognized, the present invention may be embodied within a form that does not provide all of the features and benefits set forth herein, as some features may be used or practiced separately from others.

What is claimed is:

1. A method of making a microelectromechanical system (MEMS) device, comprising:
providing a substrate;
forming a first sacrificial layer over the substrate;
forming at least one aperture in the first sacrificial layer;
forming a second sacrificial layer over the first sacrificial layer and the at least one formed aperture;
forming an electrically conductive layer over the second sacrificial layer, thereby forming a non-planar interface between the electrically conductive layer and the second sacrificial layer; and
removing the first and second sacrificial layers to form a cavity between the substrate and the electrically conductive layer.

2. The method of claim 1, wherein the substrate comprises a second electrically conductive layer.

3. The method of claim 2, wherein the second electrically conductive layer comprises indium tin oxide.

4. The method of claim 1, wherein the electrically conductive layer comprises a movable layer.

5. The method of claim 1, wherein the substrate comprises a partially reflective layer.

6. The method of claim 1, further comprising patterning the first sacrificial layer.

7. The method of claim 6, wherein the patterning comprises at least one of electron beam lithography and image transfer.

8. The method of claim 6, further comprising:
forming a support structure aperture in at least one of the sacrificial layers; and
depositing a non-conductive material into the support structure aperture.

9. The method of claim 1, wherein forming the first and second sacrificial layers comprises at least one of chemical vapor deposition, physical vapor deposition and sputtering.

10. The method of claim 1, wherein the at least one formed aperture extends entirely through the first sacrificial layer.

11. A method of making an interferometric modulator, comprising:
providing a substrate;
forming a first layer over the substrate;
forming at least one aperture in the first layer;
forming a second layer over at least a portion of the first layer and the at least one aperture, wherein the first layer is thinner than the second layer as measured perpendicular to the substrate;
forming a sacrificial layer over at least a portion of the second layer, thereby forming a non-planar interface between the sacrificial layer and the second layer; and
forming an electrically conductive layer over the sacrificial layer,
the sacrificial layer being removable to thereby form a cavity between the second layer and the electrically conductive layer.

12. The method of claim 11, further comprising forming the first layer to have a thickness of about 500 angstroms or less as measured perpendicular to the substrate.

13. The method of claim 11, wherein the first and second layers both comprise a metal.

14. The method of claim 11, wherein the first and second layers both comprise a dielectric material.

15. The method of claim 11, further comprising planarizing the sacrificial layer prior to forming the electrically conductive layer.

16. The method of claim 15, wherein planarizing comprises at least one of chemical mechanical polishing and spin coating.

17. The method of claim 11, wherein the at least one aperture in the first layer has a cross sectional dimension in a range of about 2 micrometers to about 5 micrometers as measured parallel to the substrate.

18. The method of claim 11, further comprising forming at least two apertures in the first layer, wherein the apertures are separated by a distance in a range of about 4 micrometers to about 100 micrometers.

19. The method of claim 11, wherein the at least one aperture in the first layer has a depth dimension in a range of about 100 angstroms to about 500 angstroms as measured perpendicular to the substrate.

20. The method of claim 11, further comprising patterning the first layer.

21. An unreleased interferometric modulator made by the method of claim 11.

22. The method of claim 11, further comprising removing substantially all of the sacrificial material to thereby form a cavity between the second layer and the electrically conductive layer.

23. A released interferometric modulator made by the method of claim 22.

24. The method of claim 11, wherein the at least one formed aperture extends entirely through the first layer.

25. The method of claim 11, wherein forming at least one of the first layer and the second layer comprises forming at least one of a metal layer, a dielectric layer, a partially reflective layer, a transparent layer, a second electrically conductive layer and a second sacrificial layer.

26. An unreleased microelecromechanical system (MEMS) device, comprising:
a substrate;
a discontinuous first layer over the substrate, the discontinuous first layer comprising at least one aperture;
a second layer continuous over at least a portion of the discontinuous first layer and the at least one aperture, wherein the first layer is thinner than the second layer as measured perpendicular to the substrate;
a sacrificial layer over at least a portion of the second layer;
a non-planar interface between the sacrificial layer and the second layer; and
an electrically conductive layer over the sacrificial layer;
the sacrificial layer being removable to thereby form a cavity between the second layer and the electrically conductive layer.

27. The unreleased MEMS device of claim 26, wherein the first layer has a thickness of about 500 angstroms or less as measured perpendicular to the substrate.

28. The unreleased MEMS device of claim 26, wherein the first and second layers both comprise a metal.

29. The unreleased MEMS device of claim 26, wherein the first and second layers both comprise a dielectric material.

30. The unreleased MEMS device of claim 26, wherein the discontinuous first layer comprises an oxide of silicon.

31. The unreleased MEMS device of claim 26, wherein the second layer comprises an oxide of aluminum.

32. The unreleased MEMS device of claim 26, wherein the discontinuous first layer comprises a different material than the second layer.

33. An interferometric modulator, comprising:
first means for reflecting light;
a second means for reflecting light, wherein the second means for reflecting light is capable of moving towards the first reflecting means in an actuated state;
means for reducing stiction between the first reflecting means and the second reflecting means in the actuated state, while simultaneously not substantially affecting optical properties; and
means for supporting the second reflecting means.

34. The interferometric modulator of claim 33, wherein the first reflecting means comprises a partially reflective layer.

35. The interferometric modulator of claim 33, wherein the second reflecting means comprises a movable reflective layer.

36. The interferometric modulator of claim 33, wherein the stiction reducing means comprises a continuous dielectric layer over a discontinuous layer, and further wherein a depth of the discontinuous layer is in a range of about 100 angstroms to about 500 angstroms as measured perpendicular to the first reflecting means.

37. The interferometric modulator of claim 33, wherein the supporting means comprises a support post.

38. An interferometric modulator, comprising:
a substrate;
a first discontinuous layer over at least a portion of the substrate, the discontinuous first layer comprising at least one aperture;
a second layer continuous over at least a portion of the first discontinuous layer and the at least one aperture, the second layer comprising a non-planar surface, wherein the first discontinuous layer is thinner than the second layer as measured perpendicular to the substrate;
an electrically conductive layer separated from the second layer by a cavity; and
a support structure arranged over the substrate and configured to support the electrically conductive layer.

39. The interferometric modulator of claim 38, wherein the first layer has a thickness of about 500 angstroms or less as measured perpendicular to the substrate.

40. The interferometric modulator of claim 38, wherein the first and second layers both comprise a metal.

41. The interferometric modulator of claim 38, wherein the first and second layers both comprise a dielectric material.

42. The interferometric modulator of claim 38, wherein at least one of the first discontinuous layer and the second layer comprises at least one of a metal layer, a dielectric layer, a partially reflective layer, a transparent layer, a second electrically conductive layer and a second sacrificial layer;

43. An array of interferometric modulators comprising the interferometric modulator of claim 42.

44. A display device, comprising:
an array of interferometric modulators as claimed in claim 43;
a processor that is configured to communicate with the array, the processor being configured to process image data; and
a memory device that is configured to communicate with the processor.

45. The display device of claim 44, further comprising:
a driver circuit configured to send at least one signal to the array.

46. The display device of claim 45, further comprising:
a controller configured to send at least a portion of the image data to the driver circuit.

47. The display device of claim 44, further comprising:
an image source module configured to send the image data to the processor.

48. The display device of claim 47, wherein the image source module comprises at least one of a receiver, transceiver, and transmitter.

49. The display device of claim 44, further comprising:
an input device configured to receive input data and to communicate the input data to the processor.
